(19) United States
(12) Patent Application Publication
(10) Pub. No.: US 2009/0260795 A1
(43) Pub. Date: Oct. 22, 2009

(54) ACTIVE DOOR ARRAY FOR COOLING SYSTEM

(76) Inventor: Thomas M. Perazzo, San Diego, CA (US)

Correspondence Address: KNOBBE MARTENS OLSON & BEAR LLP, 2040 MAIN STREET, FOURTEENTH FLOOR, IRVINE, CA, 92614, US

(21) Appl. No.: 12/425,224

(22) Filed: Apr. 16, 2009

Related U.S. Application Data
(60) Provisional application No. 61/045,550, filed on Apr. 16, 2008.

(51) Int. Cl. G05D 23/19; H05K 5/02; F28F 7/00; B21D 53/02

(52) U.S. Cl. 165/269; 454/184; 165/80.2; 29/890.03

(57) ABSTRACT

Systems and methods for cooling a chassis are provided. Pulsed and/or modulated air flow may be used to cool a chassis. An array of movable doors and/or baffles may be used to achieve the pulsed/modulated airflow.

### RELATED APPLICATIONS

This application claims the benefit of U.S. Provisional Patent Application No. 61/045,550, titled “ACTIVE DOOR ARRAY FOR COOLING SYSTEM”, filed Apr. 16, 2008. The disclosure of the above-reference application is considered part of the disclosure of this application and is incorporated by reference herein.

### BACKGROUND OF THE INVENTION

1. Field of the Invention

The present invention relates to cooling systems.

2. Description of the Related Technology

Many high powered electronics are cooled by the use of forced convection or in other words by flowing air over hot electronics. One example of a high powered electronic system is telecom equipment used to route calls and data. With the recent proliferation of broadband internet access, mobile phone use, and cable services, the electronic equipment behind the scenes must operate at higher speeds and under increasing load. As the traffic and speed of these computers increase, the cooling demand for these systems increases exponentially. In many cases advancing technology is slowed by thermal limitations because the electronics will self destruct if not cooled properly.

Some military computers used for defense and mobile combat vehicles and aircraft have resorted to using liquid to cool electronics to keep up with the cooling demand in harsh environments. Some technologists believe that liquid cooling may be required in the near future in telecom application due to ever increasing cooling and processing power demands. Liquid cooling or spray cooling is very expensive to implement because electronics are typically not designed to operate in liquid environments. Thus, an improved method and system for cooling is needed.

### SUMMARY

In one embodiment, the invention provides a method for controlling a chassis cooling system. The method comprises creating an air flow within a chassis and modulating at least one of the air flow and a velocity of the air flow, for a slot in the chassis.

In another embodiment, the invention provides a cooling system for a chassis. The cooling system comprises at least one air mover configured to create an air flow within a chassis and at least one baffle configured to modulate at least one of the air flow and a velocity of the air flow, for a slot in the chassis.

In yet another embodiment, the invention provides a cooling system for a chassis. The cooling system comprises means for creating an air flow within a chassis and means for modulating at least one of the air flow and a velocity of the air flow, for a slot in the chassis.

In one embodiment, the invention comprises a method of manufacturing a cooling system. The method comprises providing an air mover configured to create an air flow within a chassis. The method further comprises providing at least one baffle configured to modulate at least one of the air flow or a velocity of the air flow and positioning the baffle such that the at least one baffle is able to modulate at least one of the air flow or the velocity of the air flow for a particular slot in the chassis.

### BRIEF DESCRIPTION OF THE FIGURES

FIGS. 1a-1c show exemplary air movers that may be used by certain embodiments.

FIG. 2 shows a perspective view of a chassis using a cooling system according to one embodiment.

FIG. 3 shows a close-up perspective view of portion A as shown in FIG. 2.

FIG. 4a shows a front view of a chassis using a cooling system according to another embodiment.

FIG. 4b shows a close-up front view of portion B as shown in FIG. 4a.

FIG. 5a shows a perspective view of a cooling system according to a certain embodiment.

FIG. 5b shows a close-up perspective view of portion D as shown in FIG. 5a.

FIG. 6 shows a perspective view of a baffle according to one embodiment.

FIG. 7a shows a top view of a baffle according to another embodiment.

FIG. 7b shows a cross-sectional view of a portion of the baffle taking along the line E-E of FIG. 7a.

FIG. 8a shows a graph comparing the temperature of a chassis using normal air cooling versus the temperature of a chassis using a cooling system according to one embodiment of the invention.

FIG. 8b shows another graph comparing the temperature of a chassis using normal air cooling versus the temperature of a chassis using a cooling system according to one embodiment of the invention.

### DETAILED DESCRIPTION OF CERTAIN INVENTIVE EMBODIMENTS

Generally, electronic enclosures or chassis may have several slots or locations in which application specific boards or blades can plug into a midplane bus. Each slot may have multiple core processors or have proprietary combinations of electronic components that may dissipate more than 300W per slot.

Currently there are several manufacturers of chassis' that house electronic cards that perform necessary functions. Chassis manufactures may adhere to industry wide standards such as ATCA, PICMG, VME and cPCI so that different hardware from various vendors can operate in any chassis without requiring extensive system engineering. Chassis manufactures may strive to provide equal cooling in all slots for maximum versatility. However, once the system is configured to perform a specific application, the cooling capability may not match the heat dissipation per slot. This may be due to mismatched board airflow impedance or to different cooling requirements versus time.

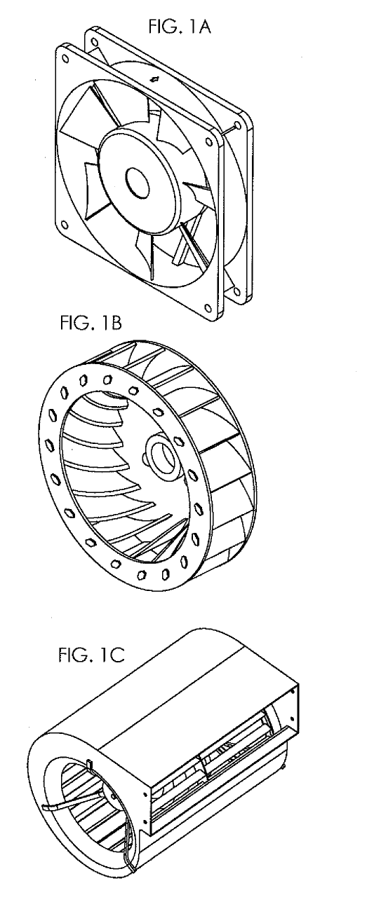

Air movers, including but not limited to fans, blowers, vacuum motors and impellers may be used to provide the cooling for a chassis. FIG. 1a shows an exemplary air mover which may be used by certain embodiments. The air mover shown in FIG. 1a is a fan. FIG. 1b shows another exemplary air mover which may be used by other embodiments. The air mover shown in FIG. 1b is a reverse impeller. FIG. 1c shows yet another exemplary air mover which may be used by certain embodiments. The air mover shown in FIG. 1c is also a fan. Although the following disclosure generally refers to fans as air moves, one of ordinary skill in the art understands that various types of air movers may be used with embodiments of the invention.

Active control circuitry is may be used to adjust the fan speed proportional to ambient room temperature fluctuation and system power dissipation needs. Fan speed control may be desirable to reduce unwanted audible noise in the rooms in which the equipment is installed and to prolong fan failure. Normal operating temperatures in a server room or central office may be in a range of 20-35 C. Abnormal conditions may reach 55 C if an HVAC system fails and the electronic system may be designed to operate for 72 hours in this adverse condition. Thermal engineers may ensure that component temperatures do not exceed their maximum allowable value (e.g. 85 C). For example, if the maximum allowable temperature is 85 C and the incoming air temperature is 55 C then the thermal budget is only 30 C. The heat must be transferred to the air in the most efficient means possible.

Today's systems attempt to flow more air through the chassis to keep up with the industries technological cooling demands. As the chassis total flow rate increases it becomes very difficult to balance or control the cooling in each board slot. State of the art airflow systems may use a large number of fans to control the air flow balance amongst all slots or may use passive air baffles to force the balance. For example, some state of the art systems utilize 20 or more fans to achieve the desired cooling requirements. The large number of fans may pose a maintenance disaster given the life a single fan may be, on average, 4 years. A large number of small fans may not be as efficient as a smaller number of large fans. However, a smaller number of large fans may have the problem of flow non-uniformity known as the “hub effect” created by the motor at the center of axial fans. Some systems may utilize reverse impeller blowers to pull air through the card slots. These systems are even more sensitive to blower placement than axial fans because of the small intake flow area versus blower diameter. Another disadvantage is several small fans or blowers may be louder than a few large ones. Phone company central offices impose sound restrictions on each piece of equipment which are often violated in favor of remaining competitive in a fast paced market.

Some systems use baffles to help with cooling. One problem with using baffles to control the distribution of airflow is that they may be inherently restrictive to airflow which is may decrease the cooling capability. These devices work by creating backpressure in areas of high flow. The flow is then attracted to areas of low pressure typically located away from the fan or blower sweet spot. Baffles may achieve balanced flow at the expense of high cooling capacity and efficiency. Another disadvantage of baffles is they may only work for a small flow range since the pressure to flow relationship is non-linear. Therefore, when the chassis fan speeds are changed, then the air flow balance may be lost. To successfully cool 300W or more per slot, a large amount of chassis air flow may be required according to relation below or improved heat transfer efficiencies have to be realized. The amount of power dissipated may be dependent on the allowable temperature rise. (10° C. is conservatively used in the industry). In the below-formula Q is the power dissipated, CFM is airflow rate, and T is temperature.

$$Q = \frac{C F M}{1.756} ( {T}_{exhaust} - {T}_{ambient} )$$

If the heat transfer from component to the air becomes more efficient then the allowable temperature rise can be higher. Therefore in addition to increasing the flow rate, increasing the heat transfer effectiveness can also help with cooling. Extensive development has occurred in the design of heat sinks, component packages, interface materials, and board designs to increase the heat transfer effectiveness. The above developments generally rely on a stream of airflow to transfer the heat. Chassis manufactures strive to provide reliable and equal air flow to all slots, but may have to provide more air flow to some slots in order to maintain a minimum air flow in others. Rather significant work has been done on the electronic board thermal design to make the maximum use of the air flow that is available.

Blower and/or fan selection must have enough flow rate capacity at the anticipated pressure drop imposed by the fully loaded chassis. For critical systems that require redundancy, generally at least two air movers are required. Two blowers operating at approximately 60% of their max RPM help mitigate two fault conditions. For example, if one of the chassis fans fail, then the second can cool the entire chassis at max RPM when the ambient room temperature is 35 C. In another example, if the HVAC system fails, then the chassis can turn both fans to full speed when the ambient temperature is 55 C.

Based on the air mover selection as discussed above, increased airflow may be achieved but the distribution of flow in each slot may be very non-uniform due to the discrete blower locations and relatively small intake areas.

Cooling requirements for a chassis may vary on a slot by slot basis, depending on the card/blade that is in slot. For example, a chassis may have 3 slots. The first two slots may use cards that operate at a lower temperature. The third slot may use a card that operates at a very high temperature. The third slot may require more air flow than the first two slots, due to the higher operating temperature of the card in the third slot. Current chassis cooling systems do not adjust the airflow in real-time on a slot by slot basis as cooling demands change during normal usage patterns of the system. Conventional cooling systems generally do not actively control how much and which slots the air flows to. Many systems are designed to operate in the worst case mode and generally do not optimize the system cooling in real-world environments.

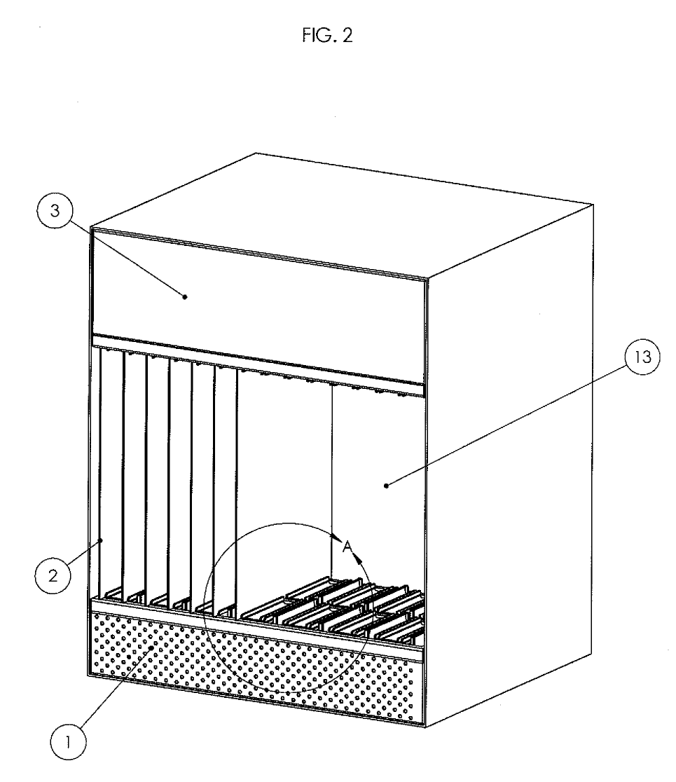

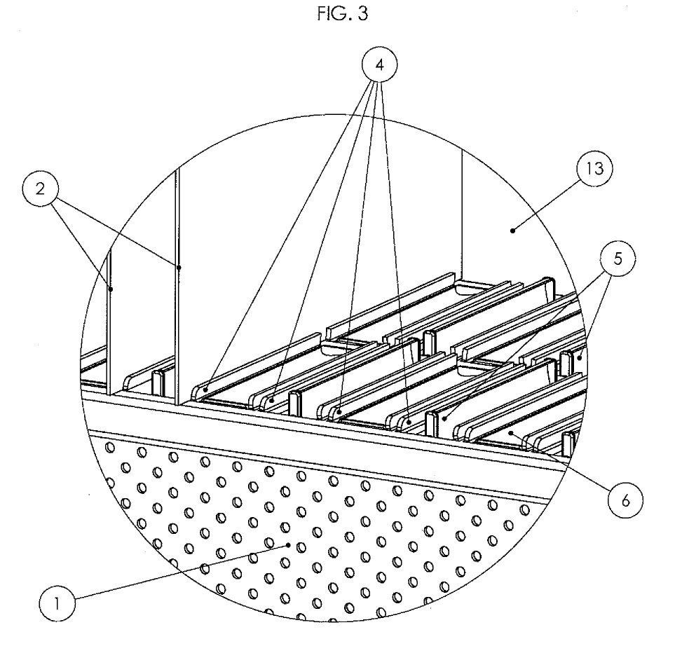

FIG. 2 is a perspective view of chassis 13 using a cooling system according to one embodiment. Air is drawn in through a perforated air intake grill 1. After air passes through the grill 1 it takes a 90 degree turn upwards through the array of cards 2. In one embodiment air movers/fans/blowers may be installed behind grill 1 underneath the card cage. In another embodiment air movers/fans/blowers may be installed in the upper portion 3 above the card cage. After air passes through the card cage it takes another 90 degree turn and exits out the rear of the chassis. Airflow may be from the bottom to the top of the chassis. However, one of skill in the art understands that embodiments of the invention may be applicable regardless of the direction of the airflow. In yet another embodiment, the air movers/fans/blowers may be positioned external to the chassis.

FIG. 3 shows a close-up perspective view of portion A as shown in FIG. 2. As shown in the figure, printed circuit cards 2 are located in slots within the chassis. The printed circuit cards 2 may have electronics present to perform a specific computing function. Metal card guides 4 allow the printer circuit cards 2 to be slid in and out of the slots. The printer circuit cards 2 may plug into the backplane 13 via blind mate connectors. In between the slots are active array doors (e.g. baffles) 5 and 6. As shown in the figure, baffles 5 are shown in the open position, allowing airflow into the slot above. Baffle 6 is shown in the closed position, preventing airflow into the slot above. One of skill in the art understands that a chassis may contain any number of slots, and that any number of baffles may be positioned in between the slots. For example, the array shown in FIG. 2 is a 14×2 array. There are fourteen columns of doors/baffles and each column has two doors/baffles. In another embodiment a 14×1 array may be used (e.g. 14 columns, which each column having one door/baffle). In another embodiment, having more doors/baffles allows for more control of the air flow within the chassis. N by I arrays may be used, where N is an integer greater than 2, and I is an integer greater than 1.

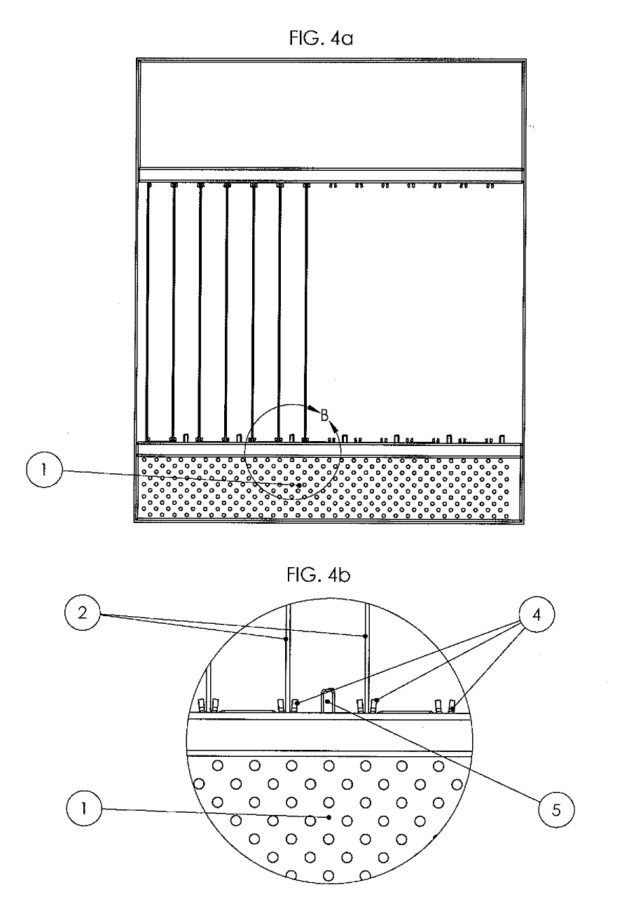

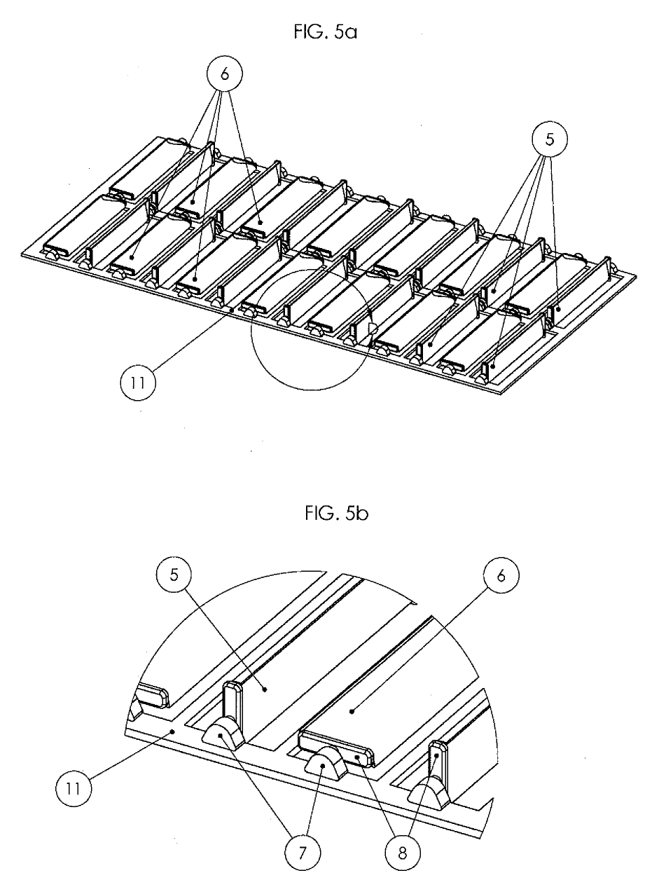

FIG. 4a shows a front view of a chassis using a cooling system according to another embodiment. Air is drawn into the chassis through grill 1. FIG. 4b shows a close-up front view of portion B as shown in FIG. 4a. Printed circuit cards 2 are held in place within the slots by metal card guides 4. As shown in FIG. 4b, baffle 5 is in the open position, thus allowing the air drawn through grill 1 to flow upwards through the slot.

FIG. 5a shows a perspective view of a cooling system according to a certain embodiment. Printed circuit board 11 distributes signals to each door/baffle in order to open or close them. Board 11 also positions each door and provides a pivot axis for the doors to open and close around. Baffles (e.g. doors) 5 are shown in an open position, allowing airflow to flow through a slot. Baffles 6 are shown in a closed position, preventing airflow from flowing through a slot. According to one embodiment, the cooling system may open or close any combination of baffles as needed to meet the cooling requirements for each slot in the chassis.

FIG. 5b shows a close-up perspective view of portion D as shown in FIG. 5a. Pivot blocks 7 support baffles 5 and 6 and provide an axis of rotation. End cap 8 comprises a pin that rotates inside pivot block 7. End cap 8 may be an injection molded part that houses a magnet. A magnetic component on the board 11 can be energized to actuate baffles into an open or closed position.

Certain embodiments of the invention may solve all the problems described above by actively controlling the airflow in each chassis slot. One embodiment utilizes an array or matrix array of doors/baffles installed at the entrance of the card cage to balance airflow to each slot without dramatically increasing the total airflow impedance. Airflow may be diverted to each slot in a pulsed fashion as the baffle or door opens and closes at each slot position at an optimum duty cycle and frequency. The duty cycle or time the door is open versus off may be unique to each slot and can change in real time. This allows the system to divert more or less airflow into each slot to either balance the flow or to customize the flow according to each slot's demands in real time. In another embodiment, 50% or more of the slot doors may remain open so as to prevent unwanted flow reductions in the chassis as a whole.

A useful benefit of pulsed flow is that pulsed airflow has the ability to increase heat transfer coefficients versus steady-state flow. While the doors may be required to balance the flow, they may also be optimized to increase the heat transfer coefficients. Some embodiments of the invention provide improved cooling efficiency with less airflow and the system can tolerate a higher delta T without increasing the component temperatures. One reason pulsed flow or unsteady flow increases the cooling effectiveness is due to the break up of thermal boundary layers. These insulating layers of air are reduced by increased turbulence created by the rapidly accelerating flow. The frequency at which the pulses occur can be optimized for each system and slot location. In one embodiment, a one second period may provide consistent increases in heat transfer.

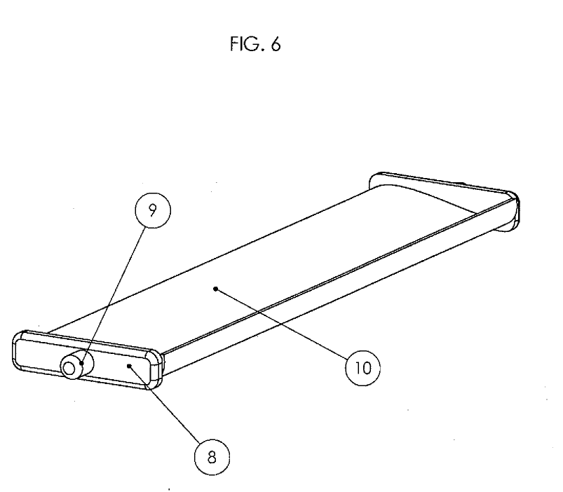

FIG. 6 shows a perspective view of a baffle 10 according to one embodiment. The axis of rotation is around the protruding pin 9. End cap 8 may comprise plastic or metal. Pin 9 may comprise plastic or metal.

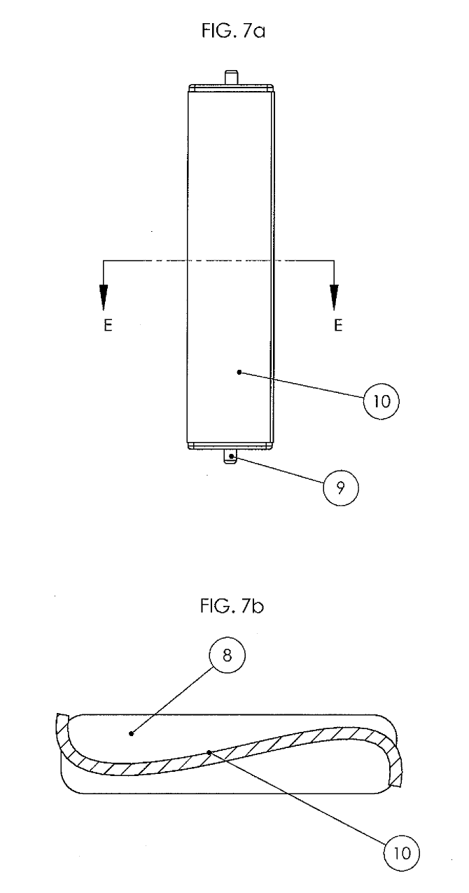

FIG. 7a shows a top view of a baffle 10 according to another embodiment. FIG. 7b shows a cross-sectional view of a portion of the baffle 10 taking along the line E-E of FIG. 7a. Baffle 10 is attached to end cap 8. Baffle 10 also has an “S” shape. This “S” shape may assist in the actuation of baffle 10. In one embodiment, the air flow may be directed by the “S” shape of the baffle 10 and may actuate the baffle 10. The shape of baffle 10 is designed to rotate in the presence of airflow. As air approaches baffle 10 from the bottom it collides with the curved surfaces of baffle 10. Air to left of pivot pin 9 is easily diverted to the left of baffle 10 due to the shape. Air to right of pivot pin 9 is not easily diverted around baffle 10. As a result, more pressure is applied to right side of baffle 10 than the left side. The resulting torque develops and the door will rotate counterclockwise in the presence of airflow even though the pivot pin 9 is centered in baffle 10. The same condition exists after the door as moved 180 degrees due to the shape of baffle 10. Although and “S” shape is shown in this embodiment, one of skill in the art understands that the baffle may comprise any curved, square, angular or straight shape.

Pulsed flows may not be achievable without movable doors or baffles because fans or blowers may not be turned on or off fast enough to realize heat transfer gains.

The baffles may be actuated with motors, magnetic, linear actuators or by the air flow itself. One embodiment does not require any motors which are prone to failure. Instead the door revolves around an axis through the center of gravity. The shape of the door may be designed so a torque is applied via the air movement created by the chassis blowers. A magnetic relay or similar friction device may be used to periodically stop the door in an open or closed position. The speed at which the door opens and closes may be designed to be a fraction of a second by utilizing the appropriate materials and optimum shapes. Although the specification discusses only a few methods and mechanisms for actuating and controlling the doors, it is understood by those skilled in the art that a variety of such methods and mechanisms exist. Embodiments of the invention may use any method or mechanism for actuation that is known in the art.

Active doors at every slot location may increase the complexity of the overall system, however the reliability may still be higher than the state of the art systems in use today. Certain embodiments of the invention allow a reduced number of air movers to be used when compared with traditional cooling systems. In some cases the number may be reduced from 20 to two which may have a dramatic effect on the reliability, as there are few air movers to maintain. In another embodiment, the active doors do not require motors and operate at a very low RPM and torque. This allows the bearing life to far exceed the life of the bearings on the fan motors. In a certain embodiment, the door array may be a field replaceable unit in the event of a damaged door array.

Certain embodiments of the invention may provide benefits over conventional cooling systems. One embodiment prevents non-uniform slot flow typical of passive systems in which the flow takes the path of least resistance. This may allow an on board system management to optimize each slot's cooling by monitoring inputs such as temperature, flow, pressure, etc. Previously wasted flow can be utilized for higher power boards with increased functionality. Another embodiment address the lack of ability, in conventional cooling systems, to change cooling needs on a slot by slot basis as the cooling demands change in real world environments. The on board system management may make changes to the cooling capacity in real time. Average audible noise levels of the cooling system may be reduced. A certain embodiment may help prevent high airflow impedance which may be caused by passive baffle schemes. The airflow impedance of the active door/baffle array may be low because the doors/baffles may be open most of the time resulting in higher average flow allowing higher power boards with increased functionality to be used. Yet another embodiment may allow for higher reliability of the air movers used to cool a chassis. The active door/baffle array allows larger more efficient fans to be used. A reduced quantity of fans dramatically reduces the probability of failure. Another embodiment may allow the cooling system to run more quietly. Slower, larger, and fewer fans may produce less audible noise and more airflow. This results in less noise pollution for maintenance staff. In one embodiment, the pulsed flow created by the active door/baffle array improves heat transfer. Higher power boards may be used with less airflow. Another embodiment may allow for lower system costs, due to the smaller number of fans required. There may also be lower maintenance costs, as certain embodiments of the invention allow a chassis to be cooled using few fans, thus reducing the number of fans to be maintained.

As discussed above, the active door/baffle array according to certain embodiments may open and close various baffles/doors for different periods of time. The amount of time a door is open compared to the amount of time the door is closed may comprise a wave form. This waveform may be changed to increase or decrease the period of the waveform. The duty cycle or time the door is open versus closed may also be changed. One embodiment may change the duty cycle or the period in order to fit the cooling needs of a chassis. One of skill in the art understands that any variation in duty cycle and period is encompassed by certain embodiments.

### Experimental Results

Preliminary tests were performed on a four slot prototype chassis to test the improved cooling effectiveness. Electronic circuit card components were monitored for temperature under two flow conditions; a) with active doors/baffles and b) without any doors/baffles. One reverse impeller was installed above the cards and operated at 60% of its maximum speed. Air was pulled from the lower front of the chassis, then through the card cage and then exhausted in the rear. A sliding door concept was used in which two of the four slots were blocked while the remaining two were open. The sliding door was actuated at 50% duty cycles for different time periods.

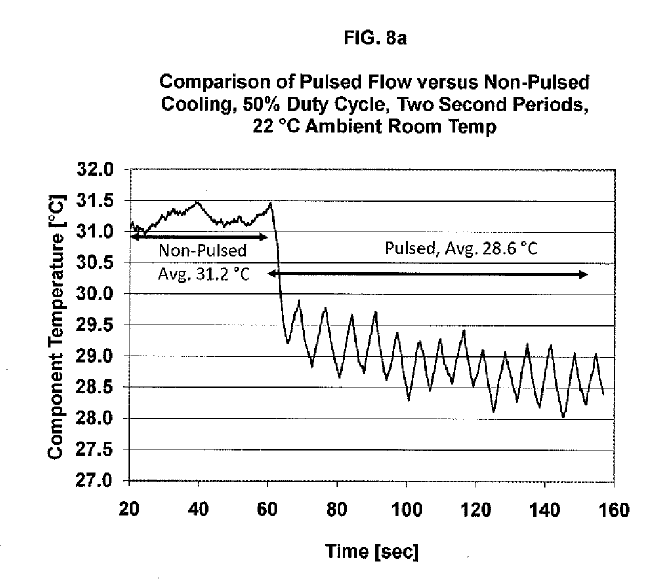

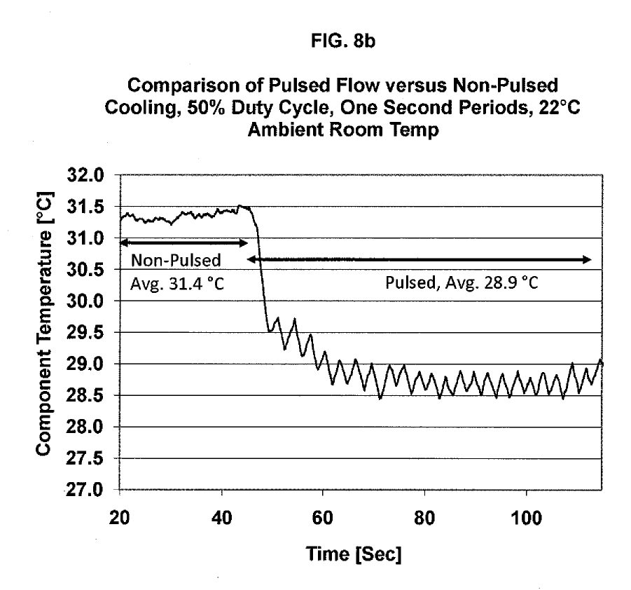

FIG. 8a shows a graph comparing the temperature of a chassis using normal air cooling versus the temperature of a chassis using a cooling system according to one embodiment of the invention. In this graph, the average temperature within the chassis using normal air cooling was 31.2 C. At 60 seconds, the active door/baffle system, according to one embodiment, was used to cool the chassis. The doors/baffles were modulated (e.g. opened and/or closed) using a two second period, at a 50% duty cycle. The doors/baffles were open for one second, then closed for one second and this pattern was repeated for the duration of the test. As shown in the graph, the average temperature for a chassis using a cooling system according to one embodiment was 28.6 C.

FIG. 8b shows another graph comparing the temperature of a chassis using normal air cooling versus the temperature of a chassis using a cooling system according to one embodiment of the invention. In this graph, the average temperature within the chassis using normal air cooling was 31.4 C. At 50 seconds, the active door/baffle system, according to one embodiment, was used to cool the chassis. The doors/baffles were modulated (e.g. opened and/or closed) using a one second period, at a 50% duty cycle. The doors/baffles were open for half a second, then closed for half a second and this pattern was repeated for the duration of the test. As shown in the graph, the average temperature for a chassis using a cooling system according to one embodiment was 28.9 C. In the above-referenced graphs, a decrease in average component temperature can be seen. For the above-referenced tests, a minimum of 1.5 deg C. reduction was obtained. The pulsed/modulated air flow may result in temperature fluctuations (about 1 degree C. for the two second period case). This fluctuation in component temperature is not expected to cause abnormal thermal cycling stress on the component since the value may be low relative to a maximum allowable temperature (e.g. 85 C).

In addition, one of skill in the art understands that there are a variety of other methods to pulse and control the airflow. For example, living hinge doors, sliding doors, eclipsing apertures, or a twisted baffle that progressively flows air from front to rear may all be used to control and pulse/modulate the amount of airflow through the cooling system.

What is claimed is:

1. A method for controlling a chassis cooling system, the method comprising:
creating an air flow within a chassis; and
modulating at least one of the air flow and a velocity of the air flow, for a slot in the chassis.

2. The method of claim 1, wherein a period of the modulation is between 0.5 seconds and 3 seconds.

3. The method of claim 1, wherein a substantial portion of the air flow is uni-directional.

4. The method of claim 1, wherein a waveform of the modulation is any combination of a sinusoidal waveform, a triangular waveform and a square waveform.

5. The method of claim 1, further comprising changing a duty cycle of a waveform of the modulation.

6. The method of claim 1, further comprising changing at least one of a period and a waveform of the modulation in response to a temperature for the slot in the chassis.

7. The method of claim 6, wherein the change in at least one of the period and the waveform is performed according to a pre-programmed algorithm which satisfies known cooling requirements for the slot.

8. The method of claim 6, wherein the change in at least one of the period and the waveform is controlled by a closed loop feedback system configured to monitor the temperature for the slot in the chassis.

9. The method of claim 1, further comprising changing at least one of the RPM and duty cycle of the baffle.

10. The method of claim 1, further comprising:
modulating at least one of the air flow and the velocity of the air flow, for a second slot in the chassis, wherein the second modulation is based on, at least in part, the first modulation.

11. The method of claim 1, wherein the modulation is based on, at least in part, cooling requirements for the slot.

12. The method of claim 10, wherein the second modulation is based on, at least in part, cooling requirements for the second slot.

13. The method of claim 10, the wherein the velocity of the air flow for the first slot is in a range of 0% to 300% of a reference velocity, wherein the reference velocity is the velocity of the air flow for the first slot when no modulation of the air flows for the first slot and the second slot is performed.

14. A cooling system for a chassis, the cooling system comprising:
at least one air mover configured to create an air flow within a chassis; and
at least one baffle configured to modulate at least one of the air flow and a velocity of the air flow, for a slot in the chassis.

15. The cooling system of claim 14, further comprising an actuator configured to control the modulation of the at least one baffle.

16. The cooling system of claim 15, wherein the actuator comprises at least one of a motor, a magnet and a solenoid.

17. The cooling system of claim 14, wherein the baffle has a shape configured to allow a torque to be applied to the baffle by the airflow.

18. The cooling system of claim 14, wherein a period of the modulation is between 0.5 seconds and 3 seconds.

19. The cooling system of claim 14, wherein a substantial portion of the air flow is uni-directional.

20. The cooling system of claim 14, wherein a waveform of the modulation is any combination of a sinusoidal waveform, a triangular waveform and a square waveform.

21. The cooling system of claim 14, wherein the system is further configured to change a duty cycle of a waveform of the modulation.

22. The cooling system of claim 14, wherein the at least one baffle is further configured to change at least one of a period and a waveform of the modulation in response to a temperature for the slot in the chassis.

23. The cooling system of claim 22, wherein the change in at least one of the period and the waveform is performed according to a pre-programmed algorithm which satisfies known cooling requirements for the slot.

24. The cooling system of claim 22, wherein the change in at least one of the period and the waveform is controlled by a closed loop feedback system configured to monitor the temperature for the slot in the chassis.

25. The cooling system of claim 14, further comprising:
a second baffle configured to modulate at least one of the air flow and a velocity of the air flow, for a second slot in the chassis, wherein the second modulation is based on, at least in part, the first modulation.

26. The cooling system of claim 14, wherein the modulation is based on, at least in part, cooling requirements for the slot.

27. The cooling system of claim 25, wherein the second modulation is based on, at least in part, cooling requirements for the second slot.

28. The cooling system of claim 14, wherein air mover is located in a position external to the chassis.

29. The cooling system of claim 14, wherein the baffle is located on a board positioned within the slot.

30. A cooling system for a chassis, the cooling system comprising:
means for creating an air flow within a chassis; and
means for modulating at least one of the air flow and a velocity of the air flow, for a slot in the chassis.

31. The cooling system of claim 30, further comprising means for modulating at least one of the air flow and the velocity of the air flow for a second slot in the chassis.

32. A method of manufacturing a cooling system, the method comprising:
providing an air mover configured to create an air flow within a chassis;
providing at least one baffle configured to modulate at least one of the air flow or a velocity of the air flow; and
positioning the baffle such that the at least one baffle is able to modulate at least one of the air flow or the velocity of the air flow for a particular slot in the chassis.

33. The method of claim 32, further comprising:
providing a second baffle configured to modulate at least one of the air flow or a velocity of the air flow; and
positioning the second baffle such that the at least one baffle is able to modulate at least one of the air flow or the velocity of the air flow for a second slot in the chassis.
